(19) United States
(12) Patent Application Publication
(10) Pub. No.: US 2025/0344615 A1
(43) Pub. Date: Nov. 6, 2025

(54) PHASE-CHANGE DEVICE

(71) Applicant: TAIWAN SEMICONDUCTOR MANUFACTURING COMPANY, LTD., Hsinchu (TW)

(72) Inventors: Yen-Liang CHU, Hsinchu (TW); Yi Ching ONG, Hsinchu (TW); Kuo-Ching HUANG, Hsinchu (TW)

(73) Assignee: TAIWAN SEMICONDUCTOR MANUFACTURING COMPANY, LTD., Hsinchu (TW)

(21) Appl. No.: 18/652,336

(22) Filed: May 1, 2024

(51) Int. Cl. H10N 70/00; H10N 70/20

(52) U.S. Cl. CPC H10N 70/8413; H10N 70/011; H10N 70/231; H10N 70/823

(57) ABSTRACT

A phase-change device includes an oxide insulator layer disposed on a semiconductor substrate, a phase-change material feature disposed in the oxide insulator layer, a heater element disposed in the oxide insulator layer and between the phase-change material feature and the semiconductor substrate, and an oxygen-free feature sandwiched between the heater element and the oxide insulator layer.

### BACKGROUND

Some phase-change materials can transition between different states, such as the amorphous/non-crystalline state and the crystalline state, resulting in changes in resistivity. This characteristic makes these phase-change materials suitable for application in some circuit components such as memory, switches, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a sectional view of a phase-change device in accordance with a first embodiment.

FIG. 2 is a schematic diagram illustrating a top view of the phase-change device in accordance with some embodiments.

FIG. 3 is a schematic diagram illustrating a sectional view of a phase-change device in accordance with a second embodiment.

FIG. 4 is a flow chart illustrating steps of a method for fabricating a phase-change device in accordance with some embodiments.

FIGS. 5 through 15 are sectional views illustrating intermediate stages of the method for fabricating a phase-change device in accordance with some embodiments.

FIG. 16 is a schematic diagram illustrating a phase-change characteristic of a phase-change material in accordance with some embodiments.

FIG. 17 is a schematic diagram illustrating operation of a radio-frequency switch in accordance with some embodiments.

FIG. 18 is a schematic diagram illustrating a sectional view of a phase-change device in accordance with a third embodiment.

FIG. 19 is a schematic diagram illustrating a sectional view of a phase-change device in accordance with a fourth embodiment.

FIG. 20 is a flow chart illustrating some replacement steps of the method for fabricating a phase-change device in accordance with some embodiments.

FIGS. 21 through 24 are sectional views illustrating the replacement steps of the method for fabricating a phase-change device in accordance with some embodiments.

FIGS. 25 through 27 are schematic diagrams illustrating multiple variations of a heater pattern.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects+10%, in some aspects+5%, in some aspects+2.5%, in some aspects+1%, in some aspects+0.5%, and in some aspects+0.1% from the specified amount, as such variations are appropriate to perform the disclosed methods or employ the disclosed compositions.

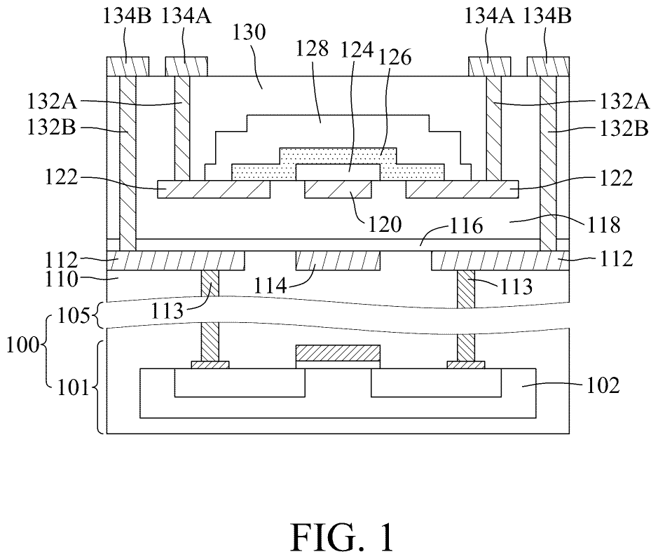

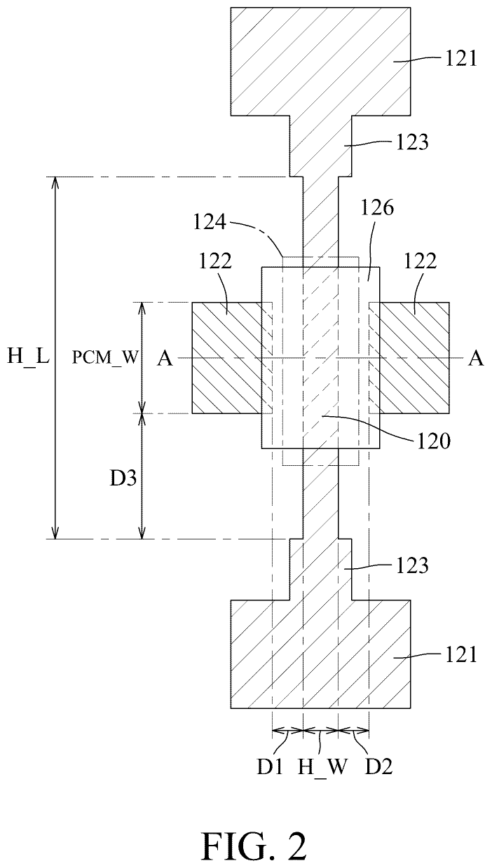

Referring to FIGS. 1 and 2, a phase-change device is illustrated in accordance with a first embodiment. In this embodiment, the phase-change device is exemplified as a radio-frequency switch (RFS), but in other embodiments, the phase-change device may be other types of electronic devices that use a phase-change material, such as phase-change memory. FIG. 2 is a top view of the phase-change device, showing a heater pattern, a signal contact pattern, and a phase-change material (PCM) pattern. The heater pattern includes patterns of a heater element 120, a pair of heater contacts 121, and a pair of connecting features 123. The heater element 120 extends in a first direction (e.g., an up-down direction from the perspective of FIG. 2). The heater contacts 121 are disposed at opposite sides of the heater element 120 in the first direction. The connecting features 123 are narrower than the heater contacts 121 and wider than the heater element 120 in a second direction (e.g., a left-right direction from the perspective of FIG. 2) transverse to the first direction. Each of the connecting features 123 is disposed between and interconnects the heater element 120 and a respective one of the heater contacts 121. In the illustrative embodiment, the heater element 120, the heater contacts 121 and the connection features 123 are formed in one piece. The signal contact pattern includes patterns of a pair of metal contacts 122 that are disposed at opposite sides of the heater element 120 in the second direction and that are spaced apart and electrically isolated from the heater element 120. The PCM pattern is a pattern of a PCM feature 126 that extends from one metal contact 122 to the other metal contact 122 in the second direction, passing over and across the heater element 120. In accordance with some embodiments, the heater element 120 is a rectangular metal strip that has a constant width in the second direction. In accordance with some embodiments, each of the heater contacts 121 has a width ranging from about 1 μm to about 10 μm in the left-right direction from the perspective of FIG. 2. In accordance with some embodiments, the heater element 120 has a length (H_L) ranging from about 5 μm to about 50 μm, and a width (H_W) ranging from about 0.1 μm to about 10 μm or from about 0.5 μm to about 3 μm based on applications, so as to provide sufficient heat to the PCM feature 126 with acceptable layout area. In accordance with some embodiments, a distance (D1, D2) between the heater element 120 and each of the metal contacts 122 ranges from about 0.1 μm to about 10 μm, thereby ensuring that the distances (D1, D2) are sufficiently large to prevent the heat generated by the heater element 120 from being conducted away by the metal contacts 122, while the phase-change device maintains an acceptable size. The distances (D1, D2) are equal in the illustrative embodiment, but this disclosure is not limited in this respect. In accordance with some embodiments, the PCM feature 126 has an effective area that has a width (PCM_W) equaling a distance by which the PCM feature 126 overlaps the metal contacts 122 in the first direction, and a length equaling a distance between the metal contacts 122 in the second direction (namely, equaling H_W+D1+D2 in the illustrative embodiment), where the width (PCM_W) ranges from about 5 μm to about 50 μm, thereby ensuring sufficiently low resistance between the metal contacts 122 when the PCM feature 126 conducts, while ensuring that the phase-change device maintains an acceptable size. In accordance with some embodiments, a distance (D3) between an end of the heater element 120 and the metal contacts 122 in the first direction ranges from about 0.1 μm to about 10 μm, so as to ensure that the distance (D3) is sufficiently large to prevent electric signals transmitted through the metal contacts 122 from being influenced by electric current flowing on the heat contacts 121 and/or the connecting features 123, while the phase-change device maintains an acceptable size. In accordance with some embodiments, each of the heater pattern, the signal contact pattern, and the PCM pattern is symmetric with respect to a center of the heater element 120 when viewed from the top, but this disclosure is not limited in this respect. FIG. 1 is a sectional view of the phase-change device taken along line A-A in FIG. 2.

Referring to FIGS. 1 and 2, the phase-change device is formed over a substrate 100. The substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. It is noted that, in this specification, the term “insulator” refers to “electrical insulator” and the term “insulate” or other forms of the verb refers to “electrically insulate,” unless otherwise specified. The insulator layer may be a buried oxide (BOX) layer, a silicon oxide layer or any other suitable layer. The insulator layer may be provided on a suitable substrate, such as silicon, glass or the like. The substrate 100 may be made of a suitable semiconductor material, such as silicon or the like. In some embodiments, the substrate 100 is a silicon substrate; and in other embodiments, the substrate 100 is made of a compound semiconductor such as silicon carbide, gallium arsenide, indium arsenide, indium phosphide or other suitable materials. In still other embodiments, the substrate 100 is made of an alloy semiconductor such as GaAsP, AlInAs, AlGaAs, GalnAs, GalnP, GaInAsP or other suitable materials.

In some embodiments, the substrate 100 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The substrate 100 may include lateral isolation features (e.g., shallow trench isolation (STI)) configured to separate various functional elements formed on the substrate 100 and/or various functional elements formed in the substrate 100.

In the illustrative embodiment, the substrate 100 includes a front-end-of-line (FEOL) portion 101 that includes semiconductor devices (e.g., a transistor 102) formed therein, and an interconnection portion 105 that is composed of one or more interconnection layers (not shown) for establishing connections among the semiconductor devices and devices in other layers. A first dielectric layer 110 is formed over the substrate 100, and is provided with multiple metal lines 112 and a heat spreader 114 disposed therein. In the illustrative embodiment, the metal lines 112 and the heat spreader 114 are formed using the same metal layer, and are spaced apart from each other. The metal lines 112 are used for transmission of electric signals, and are electrically connected to electronic components in other layers, such as transistors or other electronic components in the FEOL portion 101, or other electronic components in the interconnection portion 105 or upper layers. In the illustrative embodiment, multiple metal vias 113 are formed in the first dielectric layer 110, and extend respectively from the metal lines 112 downward to electrically connect the metal lines 112 respectively to a source and a drain of the transistor 102. The heat spreader 114 is made to assist in dissipating heat that is generated from operation of the phase-change device, extends parallel to a top surface of the substrate 100, and is a floating element that is electrically isolated from all electronic components in the substrate 100 and all electronic components on the substrate 100. In accordance with some embodiments, the first dielectric layer 110 may include, for example, silicon dioxide, undoped silicon glass (USG), a low-k material, other suitable materials, or any combination thereof. In accordance with some embodiments, the heat spreader 114 is made of a metal material having a thermal conductivity greater than about 100 W/m·K, such as Cu, other suitable metals, or any combination thereof.

A heat conductor layer 116 is disposed on and covers the first dielectric layer 110, the metal lines 112 and the heat spreader 114, and is made of an insulator material having a thermal conductivity greater than about 100 W/m·K, such as silicon carbide, other suitable insulating materials, or any combination thereof. The heat conductor layer 116 is made to assist in dissipating the heat that is generated from operation of the phase-change device, and is made to be an electrically-isolated layer to prevent the metal components such as the metal lines 112 and the heat spreader 114 from being electrically connected to each other.

A second dielectric layer 118 is disposed on the heat conductor layer 116 so that the heat conductor layer 116 is sandwiched between the first dielectric layer 110 and the second dielectric layer 118. In accordance with some embodiments, the second dielectric layer 118 may include, for example, silicon dioxide, USG, a low-k material, other suitable materials, or any combination thereof. The second dielectric layer 118 is provided with the heater element 120 and the metal contacts 122 formed therein. The heater element 120 and the metal contacts 122 are spaced apart from each other, and are formed using the same metal layer in this embodiment, but this disclosure is not limited in this respect. In accordance with some embodiments, the heater element 120 overlaps the heat spreader 114 in a third direction (e.g., an up-down direction from the perspective of FIG. 1) that is transverse to the first direction and the second direction, and is made of a metal material having a melting point greater than about 1500° C. and having a Seebeck coefficient smaller than 50 μV/K, such as tungsten, other suitable metals, or any combination thereof, so as to reduce the impact of voltage fluctuations generated during the rapid heating and cooling of the heater element 120 on electric signals transmitted through the phase-change device.

A first insulator feature 124 is disposed on the heater element 120, with the PCM feature 126 disposed thereon. In accordance with some embodiments, the PCM feature 126 is made of a phase-change material, such as GeTe, GeSeTe, other suitable phase-change materials, or any combination thereof. In the illustrative embodiment, the first insulator feature 124 is in contact with the heater element 120, and is sandwiched between the heater element 120 and the PCM feature 126. From the perspective of FIG. 2, the first insulator feature 124 is wider than the heater element 120 in the second direction, and is wider than the PCM feature 126 in the first direction, so as to electrically isolate the heater element 120 from the PCM feature 126. In accordance with some embodiments, the first insulator feature 124 is made of an insulator material that has a thermal conductivity greater than about 100 W/m·K, such as silicon nitride, diamond-like carbon, other suitable insulators, or any combination thereof, so as to facilitate heat conduction from the heater element 120 to the PCM feature 126, which would induce switching of the PCM feature 126 between a high-resistivity state (e.g., an amorphous state) and a low-resistivity state (e.g., a crystalline state). In the illustrative embodiment, the PCM feature 126 is disposed on and in contact with the metal contacts 122 and the first insulator feature 124, and spans or extends from one metal contact 122 to the other metal contact 122, passing over and across the first insulator feature 124.

A second insulator feature 128 is disposed on the top and sidewalls of the PCM feature 126, and comprehensively covers and surrounds the PCM feature 126, thereby sealing the PCM feature 126 therein, and protecting the PCM feature 126 from damage or undesired chemical reactions in subsequent processes. The second insulator feature 128 may be formed using either the same material as or a different material from the first insulator feature 124. In accordance with some embodiments, the second insulator feature 128 is made of an insulator material that has a thermal conductivity greater than about 100 W/m·K, so as to facilitate dissipation of heat that is generated from operation of the phase-change device. The first insulator feature 124, the PCM feature 126 and the second insulator feature 128 are formed in and surrounded by a third dielectric layer 130, which is disposed on the second dielectric layer 118, the heater element 120 and the metal contacts 122. The metal contacts 122 are respectively connected to metal lines 134A that are disposed on the third dielectric layer 130, through metal vias 132A that are disposed in the third dielectric layer 130 and that extend between the metal contacts 122 and the metal lines 134A. The metal vias 132A and the metal lines 134A connect the metal contacts 122 to other electronic components (not shown) that provide radio-frequency signals. In addition to the metal lines 134A, there are also metal lines 134B disposed on the third dielectric layer 130. The metal lines 134B are electrically connected to the heater contacts 121 (see FIG. 2), and are electrically connected to the source and the drain of the transistor 102, respectively, through metal vias 132B, the metal lines 112, the metal vias 113, and the interconnection portion 105 of the substrate 100. As a result, the heater contacts 121 are able to receive electric current generated by the transistor 102, and allow the electric current to flow through the heater element 120 via the connecting features 123, thereby raising a temperature of the heater element 120.

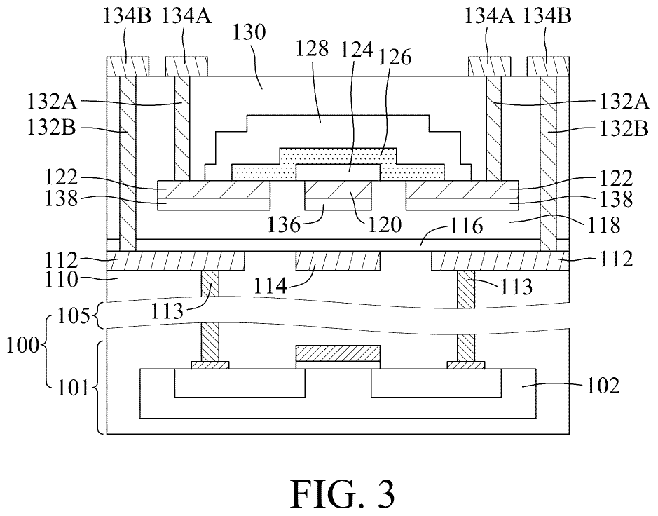

FIG. 3 illustrates a sectional view of a phase-change device in accordance with a second embodiment, which is similar to the first embodiment. When the second dielectric layer 118 is an oxide insulator layer, the heater element 120 and the metal contacts 122 may react with the oxygen in the oxide insulator layer to form metal oxide. In the second embodiment, the second dielectric layer 118 is exemplified to be an oxide insulator layer, such as a silicon dioxide layer, and the heater element 120 and the metal contacts 122 are exemplified to be made of tungsten, but this disclosure is not limited in this respect. When the heater element 120 and the metal contacts 122 are directly formed on the oxide insulator layer, a lower portion of the tungsten that is close to an interface between the tungsten and the oxide insulator layer may react with the oxygen in the oxide insulator layer to form tungsten oxide, resulting in weak adhesion or bonding between the tungsten and the oxide insulator layer, which may cause peeling issues. Therefore, the phase-change device according to the second embodiment further includes an oxygen-free feature 136 sandwiched between the heater element 120 and the second dielectric layer 118, and two oxygen-free features 138, each sandwiched between a respective one of the metal contacts 122 and the second dielectric layer 118, where the oxygen-free features 136, 138 are spaced apart from each other. In the illustrative embodiment, each of the oxygen-free features 136, 138 is sandwiched only between the second dielectric layer 118 and a bottom of the respective one of the heater element 120 and the metal contacts 122, while sidewalls of the heater element 120 and the metal contacts 122 are directly disposed on or in contact with the second dielectric layer 118, but this disclosure is not limited in this respect. In accordance with some embodiments, the oxygen-free features 136, 138 have a melting point that is greater than about 1500 K, and a coefficient of thermal expansion that is smaller than about 10⁻⁵ K⁻¹ to adapt to operation of the heater element 120 at high temperatures. In accordance with some embodiments, the oxygen-free features 136, 138 are made of, for example, a layer of silicon, a layer of silicon nitride, a layer of tungsten nitride, a layer of tungsten silicide, a layer of other suitable materials, a layer of any combination of the abovementioned materials, or any combination of the abovementioned layers. In a case where the oxygen-free features 136, 138 are layers of silicon, and the heater element 120 and the metal contacts 122 are made of tungsten, the oxygen-free features 136, 138 may include silicon nitride therein because nitrogen gas may be used during the deposition of tungsten, and a layer of tungsten silicide may be formed between the layer of silicon and each of the heater element 120 and the metal contacts 122, but this disclosure is not limited in this respect. The oxygen-free features 136, 138 are formed to prevent oxygen in the second dielectric layer 118 from reacting with metal in the heater element 120 and the metal contacts 122 to form metal oxide, thereby strengthening adhesion or bonding of the heater element 120 and the metal contacts 122 to the underlying layer. In accordance with some embodiments, a distance between the heat conductor layer 116 and the heater element 120 is in a range from about 300 angstroms to about 700 angstroms, so as to facilitate heat dissipation of the heat conductor layer 116 during the cooling of the PCM feature 126.

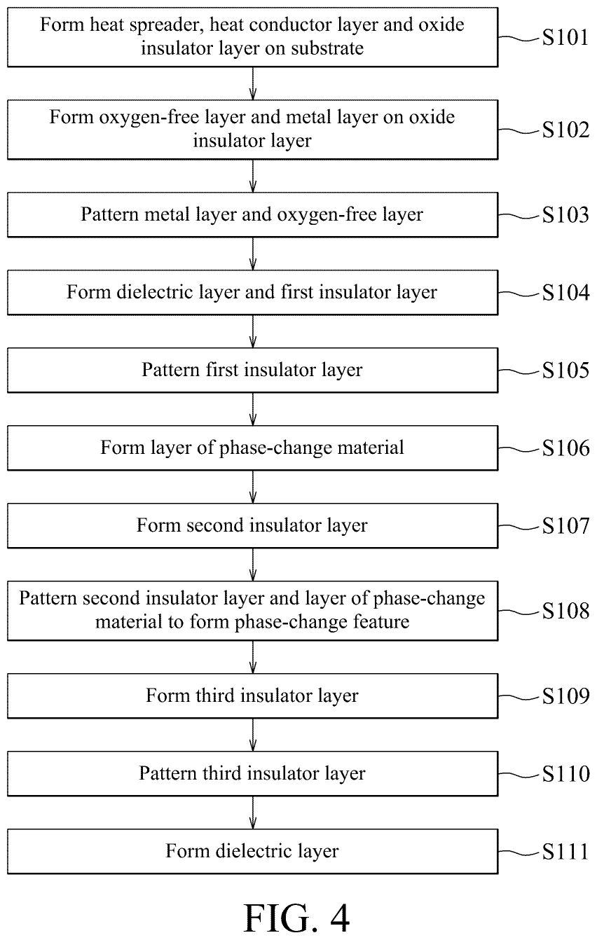

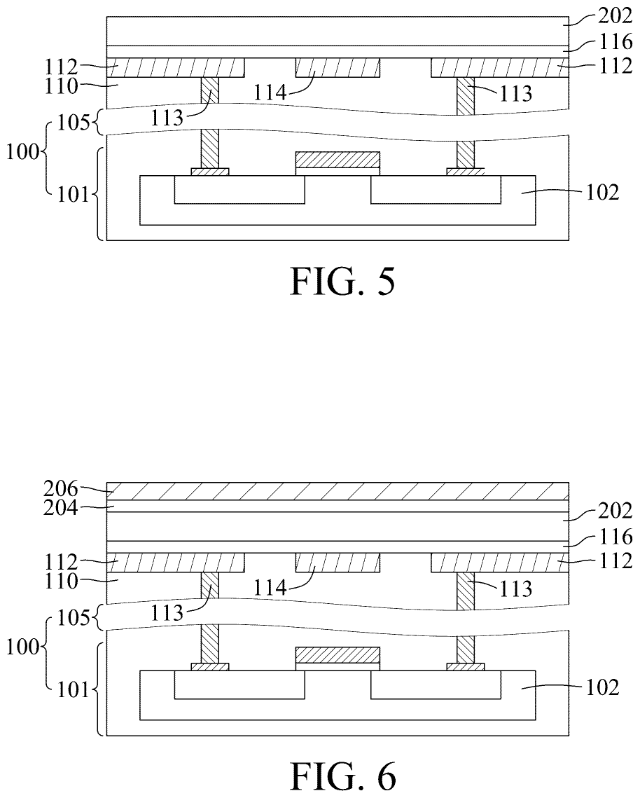

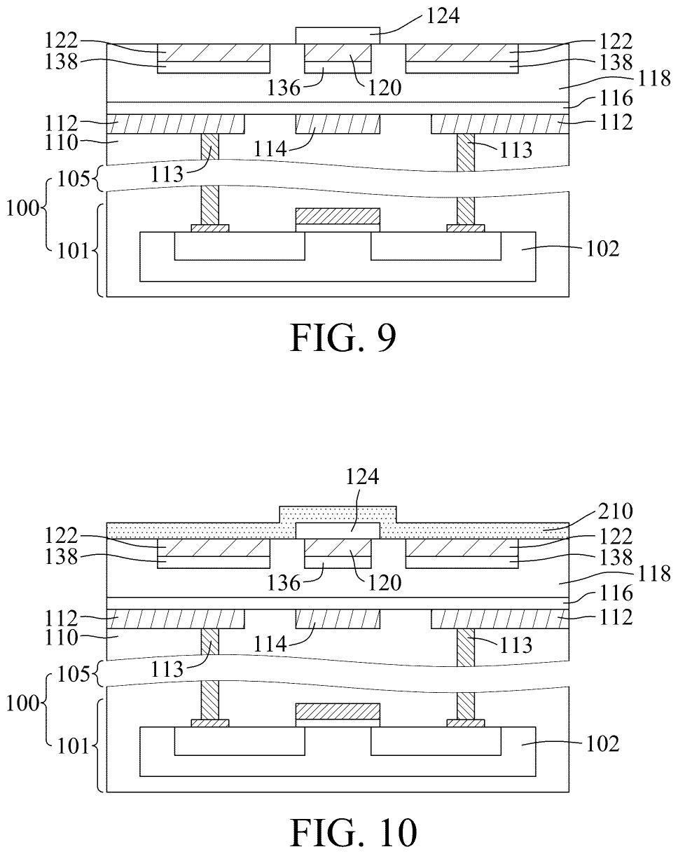

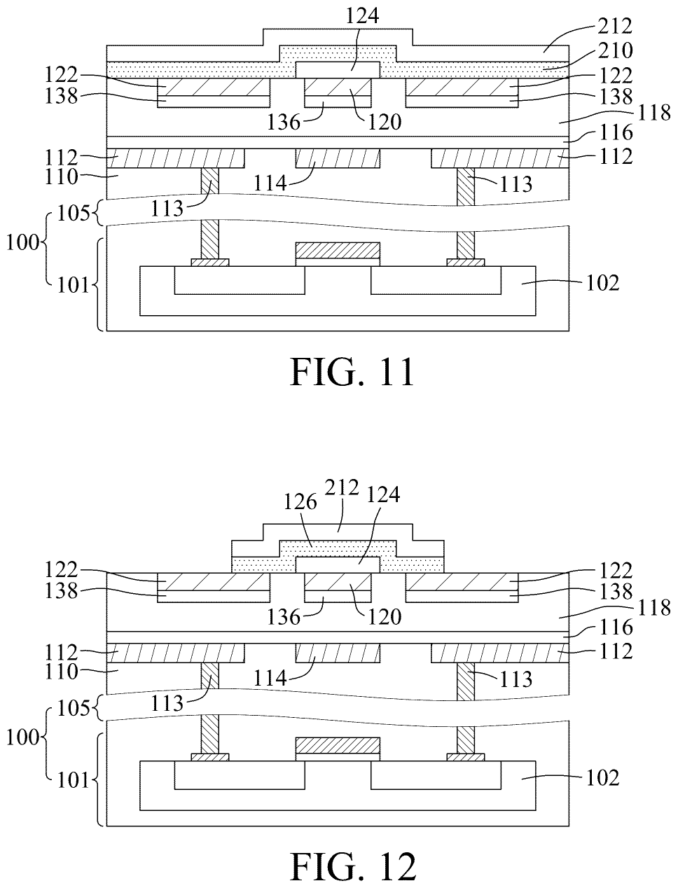

FIG. 4 is a flow chart that cooperates with FIGS. 5 to 15 to illustrate a method for fabricating a phase-change device as shown in FIG. 3.

Referring to FIGS. 4 and 5, in step S101, the substrate 100 is provided with the first dielectric layer 110 thereon. The metal lines 112 and the heat spreader 114 are formed in a top portion of the first dielectric layer 110, and the metal vias 113 are formed in the first dielectric layer 110, and extend between the metal lines 112 and the substrate 100. The heat conductor layer 116 is formed on the metal lines 112, the heat spreader 114 and a top surface of the first dielectric layer 110. An oxide insulator layer 202 is formed on the heat conductor layer 116 using, for example, physical vapor deposition (PVD), chemical vapor deposition (CVD), atomic layer deposition (ALD), other suitable deposition techniques, or any combination thereof. In accordance with some embodiments, the oxide insulator layer 202 may be a layer of silicon dioxide, USG, other suitable oxide materials, or any combination thereof.

Referring to FIGS. 4 and 6, in step S102, an oxygen-free layer 204 is formed on the oxide insulator layer 202, and a metal layer 206 is formed on the oxygen-free layer 204. In accordance with some embodiments, the oxygen-free layer 204 may be formed using, for example, PVD, CVD, ALD, other suitable deposition techniques, or any combination thereof, and include, for example, silicon, silicon nitride, other suitable materials, or any combination thereof. In the illustrative embodiment, the oxygen-free layer 204 is a layer of amorphous silicon, and has a thickness in a range from about 1 angstrom to about 100 angstroms, but this disclosure is not limited in this respect. In some embodiments, the thickness of the oxygen-free layer 204 ranges from about 30 angstroms to about 70 angstroms, so as to effectively prevent oxygen from reacting with layers above. In accordance with some embodiments, the metal layer 206 may be formed using, for example, PVD, CVD, ALD, other suitable deposition techniques, or any combination thereof. In the illustrative embodiment, the metal layer 206 has a melting point greater than about 1500° C. (e.g., a layer of tungsten in this embodiment), and has a thickness in a range from about 100 angstroms to about 2000 angstroms, but this disclosure is not limited in this respect. In accordance with some embodiments, during the deposition of the metal layer 206, nitrogen gas may be introduced into the deposition chamber, and may react with amorphous silicon to form silicon nitride in the oxygen-free layer 204. In accordance with some embodiments, a silicon nitride layer may be formed between the oxygen-free layer 204 and the metal layer 206 (represented by the line between the oxygen-free layer 204 and the metal layer 206 in FIG. 6). In accordance with some embodiments, metal nitride (e.g., tungsten nitride in this embodiment) may be formed in the oxygen-free layer 204. In accordance with some embodiments, during the deposition of the metal layer 206, the metal layer 206 may react with amorphous silicon to form metal silicide (e.g., tungsten silicide in this embodiment) in the oxygen-free layer 204. In accordance with some embodiments, a metal silicide layer (e.g., a tungsten silicide layer in this embodiment) may be formed between the oxygen-free layer 204 and the metal layer 206 (represented by the line between the oxygen-free layer 204 and the metal layer 206 in FIG. 6). In accordance with some embodiments, an intermediate layer that includes silicon nitride and metal silicide may be formed between the oxygen-free layer 204 and the metal layer 206 (represented by the line between the oxygen-free layer 204 and the metal layer 206 in FIG. 6).

Referring to FIGS. 4, 6 and 7, in step S103, the metal layer 206 and the oxygen-free layer 204 are patterned to form the oxygen-free features 136, 138, the heater element 120 and the metal contacts 122. In accordance with some embodiments, a photolithography process may be used to form an etching mask of photoresist over the metal layer 206, and the metal layer 206 may be etched using, for example, dry etching, other suitable etching techniques, or any combination thereof, and then, with the patterned metal layer 206 serving as an etching mask, the oxygen-free layer 204 may be etched using, for example, dry etching, other suitable etching techniques, or any combination thereof, so that the same pattern is formed in the metal layer 206 and the oxygen-free layer 204, but this disclosure is not limited in this respect.

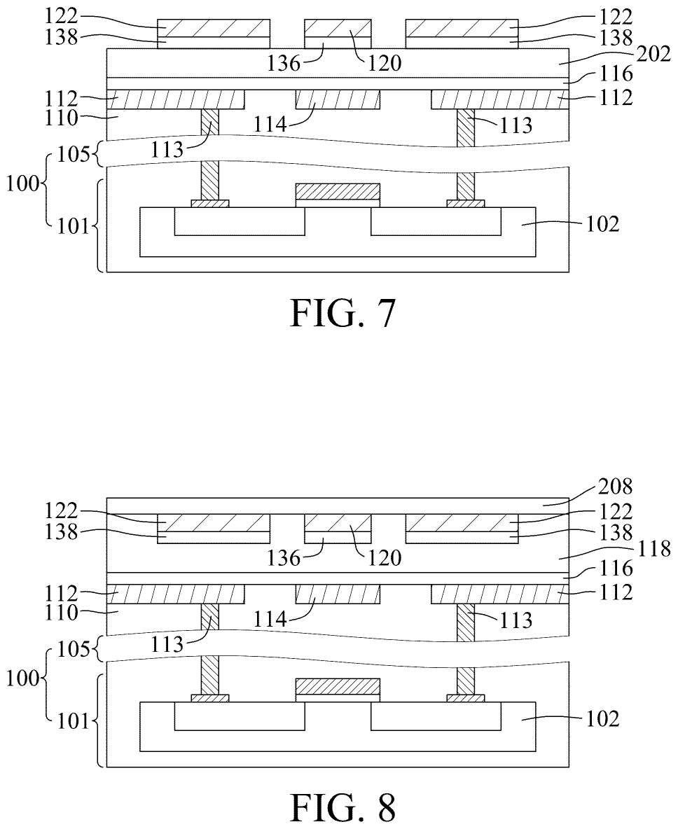

Referring to FIGS. 4 and 8, in step S104, a dielectric layer is deposited to fill in between the heater element 120 and the metal contacts 122, using, for example, PVD, CVD, ALD, other suitable deposition techniques, or any combination thereof. Then, a planarization process (e.g., chemical-mechanical planarization (CMP)) may be performed to reveal the heater element 120 and the metal contacts 122, but this disclosure is not limited in this respect. In accordance with some embodiments, the dielectric layer may be made of an oxide insulator. In the illustrative embodiment, the dielectric layer is made of the same material as the oxide insulator layer 202 (see FIG. 7), and the dielectric layer together with the oxide insulator layer 202 form the second dielectric layer 118. Then, an insulator layer 208 is formed on the second dielectric layer 118, the heater element 120 and the metal contacts 122 using, for example, PVD, CVD, ALD, other suitable deposition techniques, or any combination thereof. In accordance with some embodiments, the insulator layer 208 is made of an insulator material that has a thermal conductivity greater than about 100 W/m·K, such as silicon nitride, diamond-like carbon, other suitable insulators, or any combination thereof.

Referring to FIGS. 4, 8 and 9, in step S105, the insulator layer 208 is patterned to reveal the metal contacts 122, and to form the first insulator feature 124 that covers the heater element 120. In accordance with some embodiments, a photolithography process may be used to form an etching mask of photoresist over the insulator layer 208, and the insulator layer 208 may be etched using, for example, dry etching, other suitable etching techniques, or any combination thereof. In the illustrative embodiment, the resultant first insulator feature 124 is in contact with and completely covers the heater element 120, and is spaced apart from the metal contacts 122, but this disclosure is not limited in this respect.

Referring to FIGS. 4 and 10, in step S106, a layer 210 of a phase-change material is formed on the first insulator feature 124, the second dielectric layer 118, and the metal contacts 122 using, for example, PVD, CVD, ALD, other suitable deposition techniques, or any combination thereof. In accordance with some embodiments, the phase-change material may include, for example, GeTe, GeSeTe, other suitable phase-change materials, or any combination thereof.

Referring to FIGS. 4, 10 and 11, in step S107, an insulator layer 212 is formed on the layer 210 using, for example, PVD, CVD, ALD, other suitable deposition techniques, or any combination thereof. In accordance with some embodiments, the insulator layer 212 may be formed using either the same material as or a different material from the first insulator feature 124. In accordance with some embodiments, the insulator layer 212 is made of an insulator material that has a thermal conductivity greater than about 100 W/m·K, but this disclosure is not limited in this respect.

Referring to FIGS. 4, 11 and 12, in step S108, the insulator layer 212 and the layer 210 are patterned to form the PCM feature 126, and to partly reveal the metal contacts 122, so that each of the metal contacts 122 has a first part that is electrically connected to the PCM feature 126, and a second part that is revealed. In accordance with some embodiments, a photolithography process may be used to form an etching mask of photoresist over the insulator layer 212, and the insulator layer 212 may be etched using, for example, dry etching, other suitable etching techniques, or any combination thereof, and then, with the patterned insulator layer 212 serving as an etching mask, the layer 210 may be etched using, for example, dry etching, other suitable etching techniques, or any combination thereof, so that the same pattern is formed in the insulator layer 212 and the layer 210, but this disclosure is not limited in this respect.

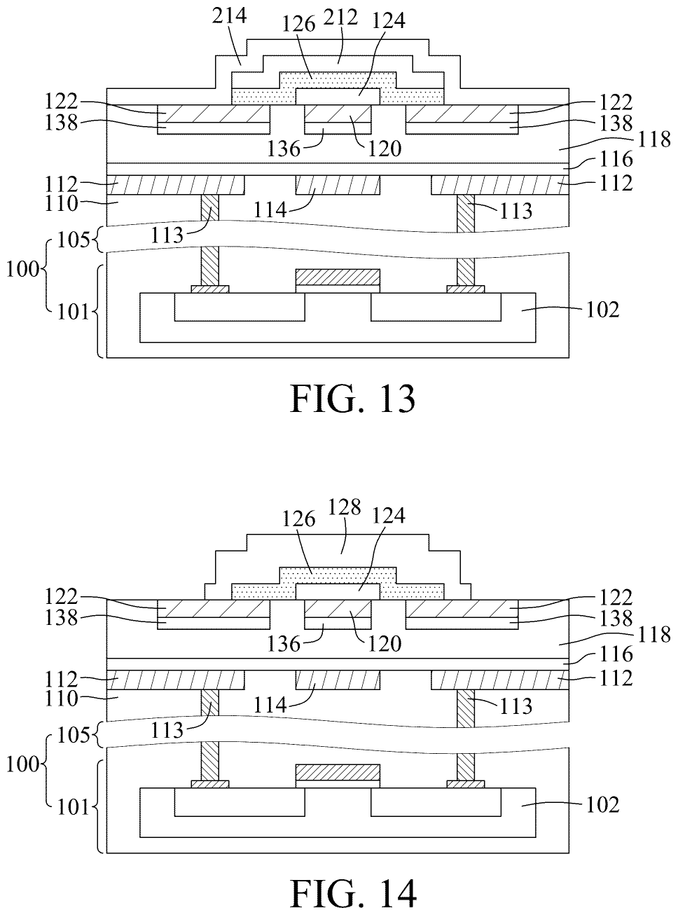

Referring to FIGS. 4 and 13, in step S109, an insulator layer 214 is formed on the patterned insulator layer 212 and the sidewalls of the PCM feature 126 using, for example, PVD, CVD, ALD, other suitable deposition techniques, or any combination thereof. In accordance with some embodiments, the insulator layer 214 may be formed using either the same material as or a different material from the insulator layer 212. In accordance with some embodiments, the insulator layer 214 is made of an insulator material that has a thermal conductivity greater than about 100 W/m·K, so as to facilitate heat dissipation during the cooling of the PCM feature 126, but this disclosure is not limited in this respect. In the illustrative embodiment, the insulator layer 214 and the insulator layer 212 are formed using the same material, but this disclosure is not limited in this respect.

Referring to FIGS. 4, 13 and 14, in step S110, the insulator layer 214 is patterned. In accordance with some embodiments, a photolithography process may be used to form an etching mask of photoresist over the insulator layer 214, and the insulator layer 214 may be etched using, for example, dry etching, other suitable etching techniques, or any combination thereof. In the illustrative embodiment, the metal contacts 122 are partly revealed after the patterning of the insulator layer 214, but this disclosure is not limited to such. In the illustrative embodiment, the patterned insulator layer 214 is wider than the patterned insulator layer 212 and the PCM feature 126, so as to ensure coverage of the sidewalls of the PCM feature 126. The patterned insulator layer 214 and the patterned insulator layer 212 cooperatively form the second insulator feature 128 (see FIG. 3).

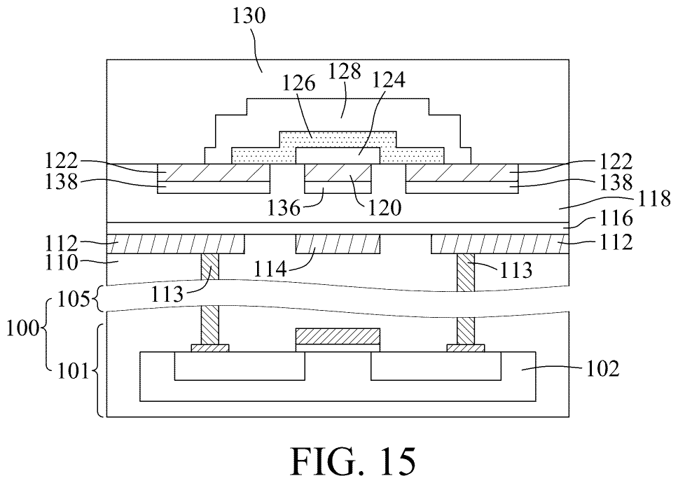

Referring to FIGS. 4 and 15, in step S111, the third dielectric layer 130 is deposited on the second dielectric layer 118, the metal contacts 122, and the second insulator feature 128. Then, the metal vias 132A, 132B and the metal lines 134A, 134B (see FIG. 3) are formed to obtain the structure as illustrate in FIG. 3.

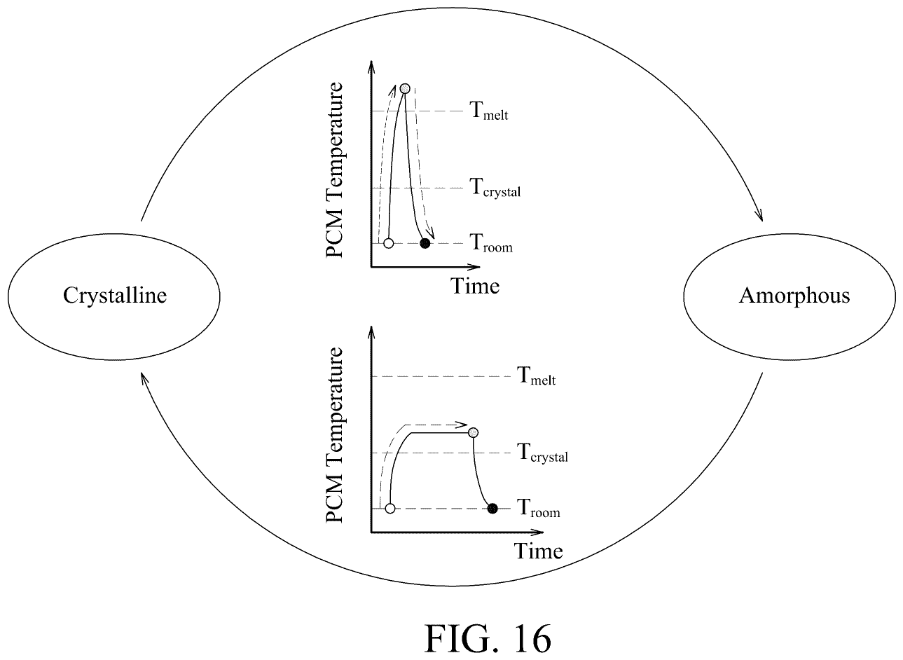

FIG. 16 illustrates a phase-change characteristic of a phase-change material used in the PCM feature 126 (see FIGS. 1 and 3) in accordance with some embodiments. In the illustrative embodiment, the phase-change material is switchable between a crystalline state (a low-resistivity state) and an amorphous state (a high-resistivity state). The phase-change material is able to transition from the crystalline state to the amorphous state by undergoing rapid heating from a room temperature (Tᵣₒₒₘ) to over its melting point (Tₘₑₗₜ), followed by a quick quenching back to the room temperature, and is able to transition from the amorphous state to the crystalline state by being heated to and held in a crystallization temperature range, which falls between a crystallization temperature (T crystal) and the melting point of the phase-change material, for a period of time, followed by a cooling process.

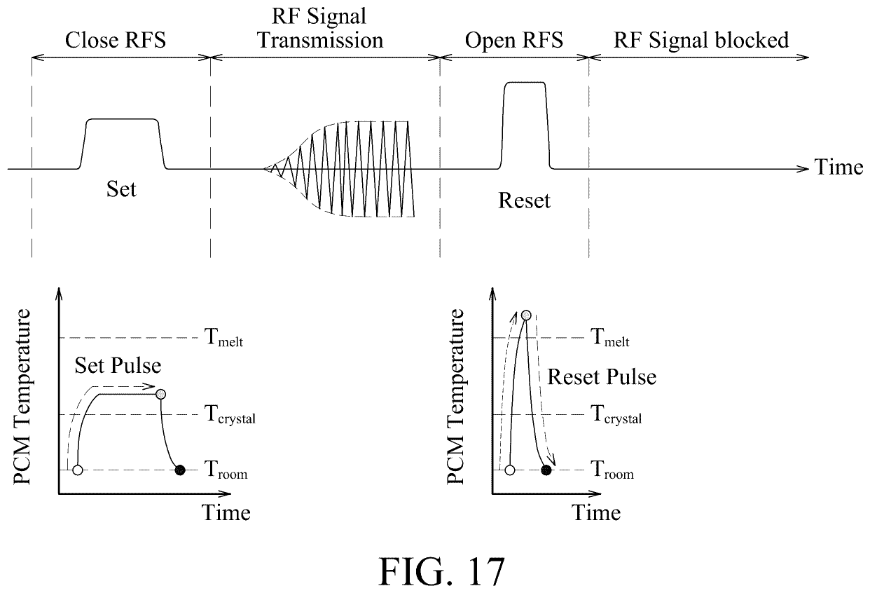

FIG. 17 illustrates operation of the radio-frequency switch in accordance with some embodiments. In order to close the radio-frequency switch (make the radio-frequency switch conduct) as illustrated in FIG. 1 or 3, a set signal is fed to the heater element 120 to induce a set pulse in the temperature of the PCM feature 126, so the PCM feature 126 transitions to the low-resistivity state, and a radio-frequency signal (RF signal) can thus be transmitted from one metal contact 122 to the other metal contact 122 through the PCM feature 126. In order to open the radio-frequency switch (make the radio-frequency switch non-conduct), a reset signal is fed to the heater element 120 to induce a reset pulse in the temperature of the PCM feature 126, so the PCM feature 126 transitions to the high-resistivity state, and signal transmission between the metal contacts 122 is blocked by the PCM feature 126.

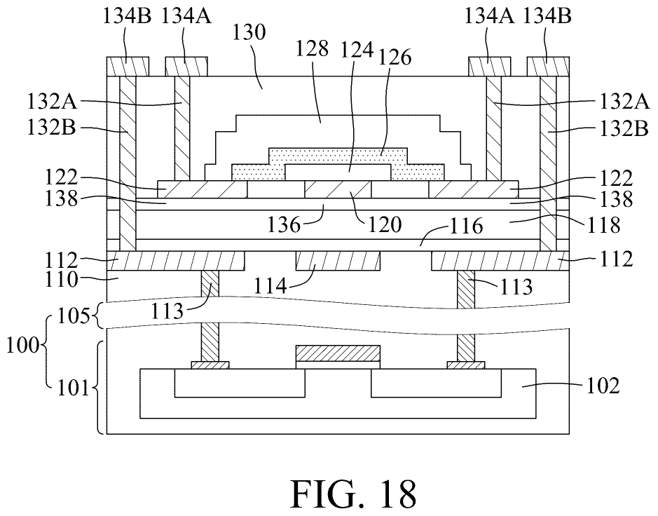

FIG. 18 illustrates a sectional view of a phase-change device in accordance with a third embodiment, which is similar to the second embodiment. The third embodiment differs from the second embodiment in that the oxygen-free features 136, 138 of the third embodiment are formed in one piece. In other words, the oxygen-free features 136, 138 extend in lateral directions and connect each other. Such a structure may be fabricated using a process flow similar to that illustrated in FIG. 4, but without performing the etching of the oxygen-free layer 204 (see FIG. 6) in step S103 after the metal layer 206 (see FIG. 6) is patterned; as a result, the process steps can be reduced, thereby saving process time. In accordance with some embodiments, the oxygen-free layer 204 in the third embodiment is made of an insulator material, so as to prevent current leakage between the heater element 120 and the metal contacts 122.

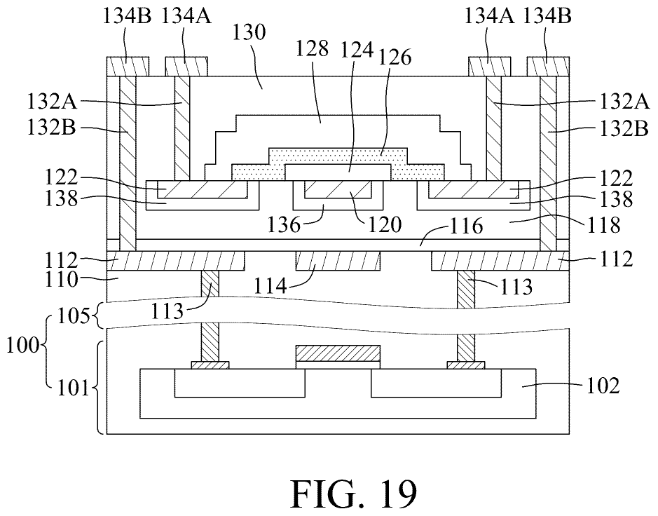

FIG. 19 illustrates a sectional view of a phase-change device in accordance with a fourth embodiment, which is similar to the second embodiment. The fourth embodiment differs from the second embodiment in that each of the oxygen-free features 136, 138 is disposed not only between the second dielectric layer 118 and the bottom of the corresponding one of the heater element 120 and the metal contacts 122, but also between the second dielectric layer 118 and the sidewalls of the corresponding one of the heater element 120 and the metal contacts 122, so as to separate the second dielectric layer 118 from the sidewalls of the corresponding one of the heater element 120 and the metal contacts 122. Each of the oxygen-free features 136, 138 is in a bowl-shape (or in a U-shape in the sectional view) and accommodates the respective one of the heater element 120 and the metal contacts 122 therein. In detail, each of the oxygen-free features 136, 138 has a bottom portion and a sidewall portion. The bottom portion of the oxygen-free feature 136 or 138 extends laterally and is sandwiched between the second dielectric layer 118 and the bottom of the corresponding one of the heater element 120 and the metal contacts 122. The sidewall portion of the oxygen-free feature 136 or 138 extends upward from the bottom portion and is sandwiched between the second dielectric layer 118 and the sidewalls of the corresponding one of the heater element 120 and the metal contacts 122. The structure of the fourth embodiment can further prevent the heater element 120 and the metal contacts 122 from reacting with the oxygen in the second dielectric layer 118 at lateral sides.

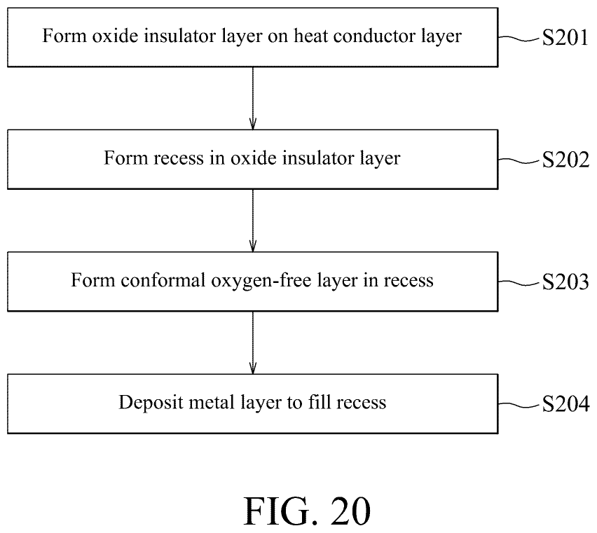

The structure of the fourth embodiment may be fabricated using a process flow similar to that illustrated in FIG. 4, but with steps S101 to S103 being replaced by steps 201 to S204 as illustrated in FIG. 20.

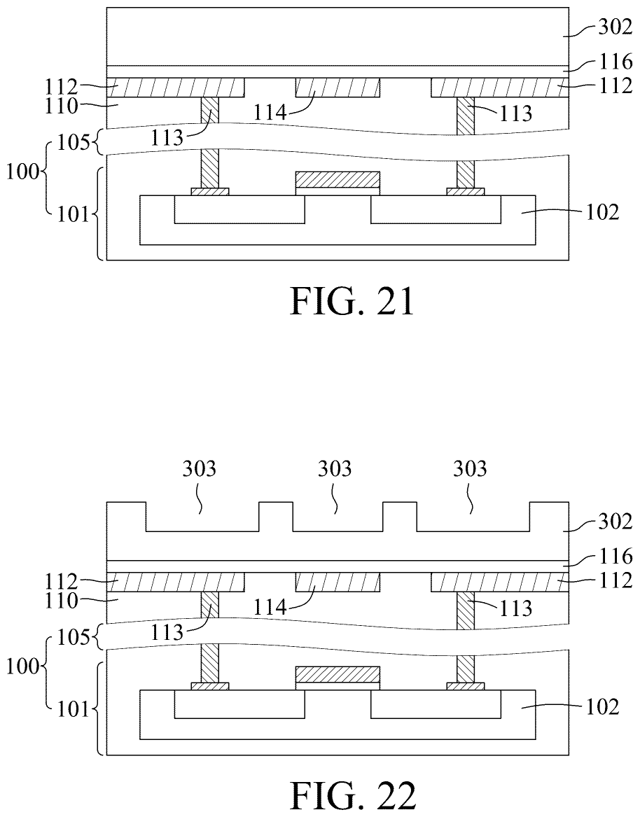

Referring to FIGS. 20 and 21, and in step S201, an oxide insulator layer 302 is formed on the heat conductor layer 116. In addition to the thickness of the oxide insulator layer 202 as shown in FIG. 5, the thickness of the oxide insulator layer 302 further includes the thickness of the heater element 120 and the thickness of the bottom portion of the oxygen-free feature 136 (see FIG. 19) that will be formed later.

Referring to FIGS. 20 and 22, in step S202, the oxide insulator layer 302 is patterned to form recesses 303 in the oxide insulator layer 302. In accordance with some embodiments, a photolithography process may be used to form an etching mask of photoresist over the oxide insulator layer 302, and the oxide insulator layer 302 may be etched using, for example, dry etching, other suitable etching techniques, or any combination thereof, to form the recesses 303.

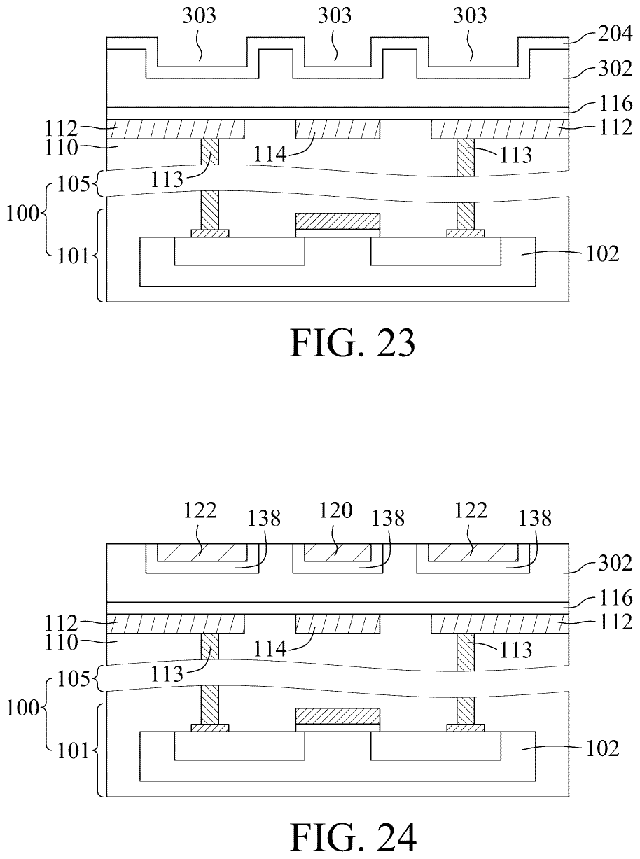

Referring to FIGS. 20 and 23, in step S203, the oxygen-free layer 204 is conformally deposited on top of the oxide insulator layer 302, and on a bottom and sidewalls of the recesses 304 using, for example, CVD, ALD, other suitable deposition techniques, or any combination thereof.

Referring to FIGS. 20, 23 and 24, in step S204, a metal layer is deposited to fill up the recesses 303, followed by a planarization process to remove excess portions of the metal layer and the oxygen-free layer 204 that extend beyond the recesses 303, so as to form the heater element 120 and the metal contacts 122.

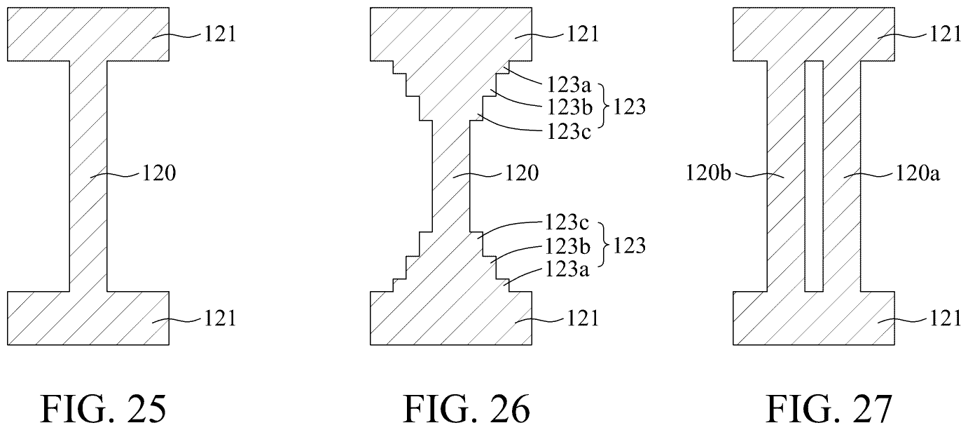

FIGS. 25 through 27 illustrate different variations of the heater pattern. In FIG. 25, the heater element 120 is directly connected to the heater contacts 121, and the connecting features 123 (see FIG. 2) are omitted. In FIG. 26, each of the connecting features 123 includes multiple segments 123a, 123b, 123c that are connected in series between the heater element 120 and the corresponding heater contact 121 and that are arranged in descending order in terms of width in the second direction, where each of the segments 123a, 123b, 123c is narrower than the corresponding heater contact 121 and wider than the heater element 120. In the illustrative embodiment, each of the segments 123a, 123b, 123c is a rectangular segment having an individual width in the second direction, where the segment 123a is narrower than the corresponding heat contact 121 in the second direction, the segment 123b is narrower than the segment 123a in the second direction, and the segment 123c is narrower than the segment 123b and wider than the heater element 120 in the second direction. In FIG. 27, the heater pattern includes a pattern of multiple heater elements 120a, 120b that are spaced apart from each other in the second direction, and each of the heater elements 120a, 120b extends between the heater contacts 121 in the first direction. This configuration may be suitable for the PCM feature 126 (see FIG. 2) with a greater width. In the illustrative embodiment, the heater elements 120a and 120b are parallel to each other, but this disclosure is not limited in this respect. In accordance with some embodiments, a distance between adjacent heater elements 120a, 120b ranges from about 0.1 μm to 1 μm, so that the PCM feature 126 (see FIG. 2) can have a uniform distribution of heat, thereby preventing a temperature at a portion of the PCM feature 126 (see FIG. 2) that corresponds in position to the gap between the heater elements 120a, 120b from being too low to induce the phase change.

In accordance with some embodiments, a phase-change device is provided to include an oxide insulator layer disposed on a semiconductor substrate, a PCM feature disposed in the oxide insulator layer, a heater element disposed in the oxide insulator layer and disposed between the PCM feature and the semiconductor substrate, and a first oxygen-free feature sandwiched between the heater element and the oxide insulator layer.

In accordance with some embodiments, the first oxygen-free feature is a layer of silicon.

In accordance with some embodiments, the heater element includes tungsten, and the phase-change device further includes a layer of tungsten silicide sandwiched between the first oxygen-free feature and the heater element.

In accordance with some embodiments, the phase-change device further includes a layer of silicon nitride sandwiched between the first oxygen-free feature and the heater element.

In accordance with some embodiments, the heater element includes tungsten, and the first oxygen-free feature is one of a layer of silicon nitride, a layer of tungsten silicide, and a layer of tungsten nitride.

In accordance with some embodiments, the first oxygen-free feature is disposed between a bottom of the heater element and the oxide insulator layer and between a sidewall of the heater element and the oxide insulator layer.

In accordance with some embodiments, the phase-change device further includes a first metal contact, a second metal contact, a second oxygen-free feature, and a third oxygen-free feature. The first metal contact is disposed in the oxide insulator layer and is electrically connected to the PCM feature. The second metal contact is disposed in the oxide insulator layer, is spaced apart from the first metal contact, and is electrically connected to the PCM feature. The second oxygen-free feature is sandwiched between the first metal contact and the oxide insulator layer. The third oxygen-free feature is sandwiched between the second metal contact and the oxide insulator layer. The heater element is spaced apart and electrically isolated from the PCM feature.

In accordance with some embodiments, the first oxygen-free feature, the second oxygen-free feature and the third oxygen-free feature are made of an insulator material and are formed in one piece.

In accordance with some embodiments, the phase-change device further includes a first insulator feature and a second insulator feature. The first insulator feature is made of a material that has a thermal conductivity greater than 100 W/m·K, and is disposed between the heater element and the PCM feature. The second insulator feature is disposed on a top and sidewalls of the PCM feature.

In accordance with some embodiments, a method is provided for fabricating a phase-change device. In one step, an oxide insulator layer is formed on a semiconductor substrate. In one step, an oxygen-free layer is formed on the oxide insulator layer. In one step, a metal layer is formed on the oxygen-free layer, where the metal layer has a melting point greater than 1500° C. In one step, the metal layer is patterned to form a heater element. In one step, a phase-change material (PCM) feature is formed over the heater element.

In accordance with some embodiments, the oxygen-free layer is a layer of amorphous silicon.

In accordance with some embodiments, the metal layer includes tungsten, and the method further includes forming a layer of tungsten silicide between the forming of the oxygen-free layer and the forming of the metal layer.

In accordance with some embodiments, the method further includes a step of forming a layer of silicon nitride between the forming of the oxygen-free layer and the forming of the metal layer.

In accordance with some embodiments, the method further includes a step of patterning the oxide insulator layer to form a recess in the oxide insulator layer. The step of forming of the oxygen-free layer includes conformally depositing the oxygen-free layer on a bottom and sidewalls of the recess that is formed in the oxide insulator layer. The step of forming of the metal layer fills up the recess with the metal layer. The step of patterning of the metal layer includes removing an excess portion of the metal layer that extends beyond the recess.

In accordance with some embodiments, the step of patterning of the metal layer further forms a first metal contact and a second metal contact, and the first metal contact, the second metal contact and the heater element are spaced apart from each other. The PCM feature is formed to be electrically connected to the first metal contact and the second metal contact, and to be electrically isolated from the heater element.

In accordance with some embodiments, the step of forming of the PCM feature includes several sub-steps. In one sub-step, a first insulator feature is formed on the heater element. In one sub-step, a layer of a phase-change material is formed on the first insulator feature, the first metal contact and the second metal contact. In one sub-step, a first insulator layer is formed on the layer of the phase-change material. In one sub-step, the first insulator layer and the layer of the phase-change material are patterned to form the PCM feature in the layer of the phase-change material. In one sub-step, a second insulator layer is formed on the first insulator layer thus patterned and on sidewalls of the PCM feature.

In accordance with some embodiments, the method further includes a step of, after the patterning of the metal layer, etching the oxygen-free layer with the metal layer thus patterned serving as an etching mask.

In accordance with some embodiments, a method is provided for fabricating a phase-change device. In one step, an oxide insulator layer is formed over a semiconductor substrate. In one step, an oxygen-free layer is formed on the oxide insulator layer. In one step, a heater element is formed on the oxygen-free layer, where the heater element is made of a metal material having a melting point greater than 1500° C. In one step, an insulator feature is formed over the heater element, where the insulator feature has a thermal conductivity greater than 100 W/m·K. In one step, a phase-change material (PCM) feature is formed over the insulator feature.

In accordance with some embodiments, in one step, a heat spreader is formed in a dielectric layer over the semiconductor substrate, where the heat spreader is made of a metal material. In one step, a heat conductor layer is formed on the heat spreader, where the heat conductor layer is made of an insulator material having a thermal conductivity greater than 100 W/m·K. The oxide insulator layer is formed on the heat conductor layer, and the heater element overlaps the heat spreader.

In accordance with some embodiments, the heat spreader extends in a plane that is parallel to a surface of the semiconductor substrate, and is electrically isolated from all electronic components in the semiconductor substrate and all electronic components on the semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A phase-change device, comprising:
an oxide insulator layer disposed on a semiconductor substrate;
a phase-change material (PCM) feature disposed in the oxide insulator layer;
a heater element disposed in the oxide insulator layer, and disposed between the PCM feature and the semiconductor substrate; and
a first oxygen-free feature sandwiched between the heater element and the oxide insulator layer.

2. The phase-change device according to claim 1, wherein the first oxygen-free feature is a layer of silicon.

3. The phase-change device according to claim 2, wherein the heater element includes tungsten, and the phase-change device further comprises a layer of tungsten silicide sandwiched between the first oxygen-free feature and the heater element.

4. The phase-change device according to claim 2, further comprising a layer of silicon nitride sandwiched between the first oxygen-free feature and the heater element.

5. The phase-change device according to claim 1, wherein the heater element includes tungsten, and the first oxygen-free feature is one of a layer of silicon nitride, a layer of tungsten silicide, and a layer of tungsten nitride.

6. The phase-change device according to claim 1, wherein the first oxygen-free feature is disposed between a bottom of the heater element and the oxide insulator layer and between a sidewall of the heater element and the oxide insulator layer.

7. The phase-change device according to claim 1, further comprising:
a first metal contact disposed in the oxide insulator layer and electrically connected to the PCM feature;
a second metal contact disposed in the oxide insulator layer, spaced apart from the first metal contact, and electrically connected to the PCM feature;
a second oxygen-free feature sandwiched between the first metal contact and the oxide insulator layer; and
a third oxygen-free feature sandwiched between the second metal contact and the oxide insulator layer;
wherein the heater element is spaced apart and electrically isolated from the PCM feature.

8. The phase-change device according to claim 7, wherein the first oxygen-free feature, the second oxygen-free feature and the third oxygen-free feature are made of an insulator material and are formed in one piece.

9. The phase-change device according to claim 1, further comprising:
a first insulator feature made of a material that has a thermal conductivity greater than 100 W/m·K, and disposed between the heater element and the PCM feature; and
a second insulator feature disposed on a top and sidewalls of the PCM feature.

10. The phase-change device according to claim 1, further comprising a pair of heater contacts disposed at opposite sides of the heater element for receiving electric current that is to raise a temperature of the heater element, and a pair of connecting features each being disposed between and interconnecting the heater element and a respective one of the heater contacts,
wherein the connecting features are narrower than the heater contacts and wider than the heater element.

11. A method for fabricating a phase-change device, comprising:
forming an oxide insulator layer on a semiconductor substrate;
forming an oxygen-free layer on the oxide insulator layer;
forming a metal layer on the oxygen-free layer, the metal layer having a melting point greater than 1500° C.;
patterning the metal layer to form a heater element; and
forming a phase-change material (PCM) feature over the heater element.

12. The method according to claim 11, wherein the oxygen-free layer is a layer of amorphous silicon.

13. The method according to claim 12, wherein the metal layer includes tungsten, and the method further comprises forming a layer of tungsten silicide between the forming of the oxygen-free layer and the forming of the metal layer.

14. The method according to claim 12, further comprising forming a layer of silicon nitride between the forming of the oxygen-free layer and the forming of the metal layer.

15. The method according to claim 11, further comprising patterning the oxide insulator layer to form a recess in the oxide insulator layer;
wherein the forming of the oxygen-free layer includes conformally depositing the oxygen-free layer on a bottom and sidewalls of the recess that is formed in the oxide insulator layer;
wherein the forming of the metal layer fills up the recess with the metal layer; and
wherein the patterning of the metal layer includes removing an excess portion of the metal layer that extends beyond the recess.

16. The method according to claim 11, wherein the patterning of the metal layer further forms a first metal contact and a second metal contact, and the first metal contact, the second metal contact and the heater element are spaced apart from each other; and
wherein the PCM feature is formed to be electrically connected to the first metal contact and the second metal contact, and to be electrically isolated from the heater element.

17. The method according to claim 16, wherein the forming of the PCM feature includes:
forming a first insulator feature on the heater element;
forming a layer of a phase-change material on the first insulator feature, the first metal contact and the second metal contact;
forming a first insulator layer on the layer of the phase-change material;
patterning the first insulator layer and the layer of the phase-change material to form the PCM feature in the layer of the phase-change material; and
forming a second insulator layer on the first insulator layer thus patterned and on sidewalls of the PCM feature.

18. The method according to claim 11, further comprising, after the patterning of the metal layer, etching the oxygen-free layer with the metal layer thus patterned serving as an etching mask.

19. A method for fabricating a phase-change device, comprising:
forming an oxide insulator layer over a semiconductor substrate;
forming an oxygen-free layer on the oxide insulator layer;
forming a heater element on the oxygen-free layer, the heater element being made of a metal material having a melting point greater than 1500° C.;
forming an insulator feature over the heater element, the insulator feature having a thermal conductivity greater than 100 W/m·K; and
forming a phase-change material (PCM) feature over the insulator feature.

20. The method according to claim 19, further comprising:
forming a heat spreader in a dielectric layer over the semiconductor substrate, where the heat spreader is made of a metal material; and
forming a heat conductor layer on the heat spreader, where the heat conductor layer is made of an insulator material having a thermal conductivity greater than 100 W/m·K;
wherein the oxide insulator layer is formed on the heat conductor layer, the heat spreader is electrically isolated from all electronic components in the semiconductor substrate and all electronic components on the semiconductor substrate, and the heater element overlaps the heat spreader.
